(19) United States
(12) Patent Application Publication
(10) Pub. No.: US 2003/0143327 A1
(43) Pub. Date: Jul. 31, 2003

(54) Method for producing a carbon nanotube

(76) Inventors: Rudiger Schlaf, Lutz, FL (US); Deron A. Walters, Orlando, FL (US); Zhifeng Ren, Newton, MA (US)

Correspondence Address: The Pinehurst Office Center, Suite 101, 39400 Woodward Avenue, Bloomfield Hills, MI, 48304-5151, US

(21) Appl. No.: 10/310,219

(22) Filed: Dec. 5, 2002

Related U.S. Application Data
(60) Provisional application No. 60/319,024, filed on Dec. 5, 2001.
(60) Provisional application No. 60/319,026, filed on Dec. 6, 2001.
(60) Provisional application No. 60/319,182, filed on Apr. 12, 2002.

(51) Int. Cl. C23C 16/26; B05D 1/32

(52) U.S. Cl. 427/249.1; 427/282

(57) ABSTRACT

A method of producing a carbon nanotube is disclosed. The carbon nanotube is used with an atomic force microscope that includes a cantilever having a tip culminating with an apex. A catalytic material is deposited onto the apex of the tip of the atomic force microscope, and the catalytic material is subjected to chemical vapor deposition. This initiates growth of the carbon nanotube such that the carbon nanotube extends from the apex of the tip.

### RELATED APPLICATIONS

This patent application claims priority to and all advantages of U.S. Provisional Patent Application Nos. 60/319,024; 60/319,026; 60/319,182; and 60/319,183, which were filed on Dec. 5, 2001; Dec. 6, 2001; Apr. 12, 2002; and Apr. 12, 2002, respectively.

### BACKGROUND OF THE INVENTION

1. Field of the Invention

A method for producing a carbon nanotube (CNT), specifically for growing a carbon nanotube on an apex of a cantilever for use with atomic force microscopes.

2. Description of the Related Art

The related art includes many known methods for producing carbon nanotubes (CNT). One such method includes growing CNTs on an oxidized silicon substrate. A cantilever having a tip with an apex is coated with glue and the apex is brought into contact with the CNT. This is commonly referred to as a “pick-up” procedure. The CNT adheres to the glue and the glue is cured. The cantilever then has the CNT attached at the apex. The related art cantilevers tips are prepared from lithography and chemical etch processes. The tips typically have a pyramidal or conical shape.

The related art is characterized by one or more inadequacies. The related art methods do not allow for precisely positioning the CNT onto the apex of the cantilever. The “pick-up” method only assures that the CNT is attached somewhere on the tip of the cantilever. Also, the glue used to secure the CNT may have defects that allow the CNT to break easily from the tip. The related art tips are unsuitable for accurate measurement of steep-walled high aspect ratio features. Also, the related art methods do not allow repeatable procedures suitable for mass production of the cantilevers with the CNT tips thereby stifling advances in the field of nanotechnology.

### SUMMARY OF THE INVENTION AND ADVANTAGES

A method of producing a carbon nanotube is disclosed. The carbon nanotube produced according to the subject invention is used with an atomic force microscope that includes a cantilever having a tip that culminates with an apex. The method includes the steps of depositing a catalytic material onto the apex of the tip of the atomic force microscope, and subjecting the catalytic material to chemical vapor deposition to initiate growth of the carbon nanotube such that the carbon nanotube extends from the apex of the tip.

The subject invention overcomes the inadequacies of the related art methods. The subject invention allows for precise positioning of CNTs having increased stability at the apex of the cantilever for use with AFMs. The CNT is suited for accurately measuring steep-walled high aspect ratio features. Also, the method of the subject invention allows for the CNTs to be mass produced thereby making the cantilever with CNT tips widely available for increased study and advances in the field of nanotechnology.

### BRIEF DESCRIPTION OF THE DRAWINGS

Other advantages of the present invention will be readily appreciated as the same becomes better understood by reference to the following detailed description when considered in connection with the accompanying drawings wherein:

FIG. 1 is a side view of an atomic force microscope having a carbon nanotube (CNT) attached to an apex of a tip of a cantilever;

FIG. 2 is an illustration of the subject invention depicting a method of growing the CNT on the cantilever;

FIG. 3 is an illustration of the subject invention depicting another method of growing the CNT on the cantilever;

FIG. 4 is a perspective view of the cantilever having a single CNT grown from the apex;

FIG. 5 is an illustration of the subject invention depicting a yet another method of growing the CNT on the cantilever;

FIG. 6 is an illustration of the subject invention depicting still another method of growing the CNT on the cantilever;

FIG. 7 is an illustration of the subject invention depicting still a further method of growing the CNT on the cantilever;

FIG. 8 an illustration depicting a method strengthening the CNT grown on the cantilever yielding extended stability; and

FIG. 9 is a perspective view of the CNT grown on sockets.

### DETAILED DESCRIPTION OF THE PREFERRED EMBODIMENT

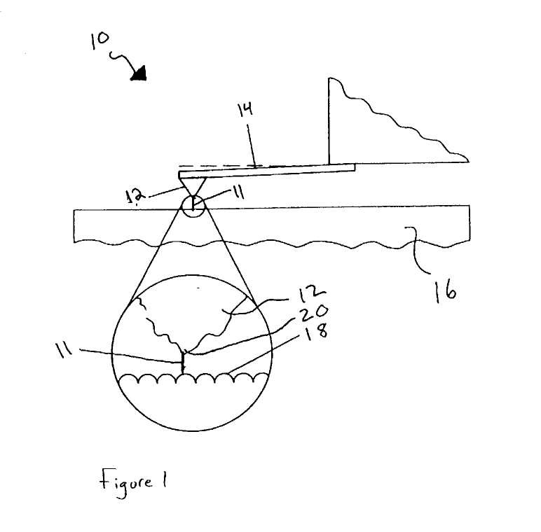

Referring to the Figures, wherein like numerals indicate like or corresponding parts throughout the several views, a method for producing a carbon nanotube (CNT) 11 is disclosed. The CNT 11 is for use with an atomic force microscope (AFM) 10 as shown generally in FIG. 1. However, the CNT 11 may also be used on other devices for manipulating nanoparticles. The AFM 10 includes a cantilever 14 having a tip 12 that culminates with an apex 20. Generally, the method includes the steps of depositing a catalytic material 22 onto the apex 20 of the tip 12 of the AFM 10, and subjecting, i.e., exposing, the catalytic material 22 to chemical vapor deposition (CVD) to initiate growth of the CNT 11 such that the CNT 11 extends from the apex 20 of the tip 12. Throughout the description herein, the catalytic material 22 may also be referred to as catalyst 22 and catalyst material 22.

The AFM 10 is a mechano-optical instrument, which detects atomic-level forces through optical measurements of movements of the CNT 11 on a tip 12 of a cantilever 14 as the CNT 11 passes over a substrate 16. AFM 10 is a method of measuring surface 18 topography of the substrate 16 on a scale from angstroms to 100 microns. The CNT 11 is held several nanometers above the surface 18 using a feedback mechanism that measures surface 18 and tip 12 interactions on the scale of nanoNewtons.

The subject invention is directed towards a variety of ways to initiate selective growth of a single CNT 11 on the apex 20 of the AFM 10 cantilever 14. An isolated small patch of catalyst 22 material is deposited at the cantilever 14 apex 20 where a CNT 11 can be grown by CVD. The catalyst 22 includes, but is not limited to, Ni, Co, Fe, and combinations thereof.

CVD is a chemical reaction that transforms gaseous molecules, called precursors, into a solid material, in the form of thin film, on the surface of the cantilever 14. Many different precursors may be utilized with the subject invention. Common gaseous precursors are selected from the group consisting of hydrides, halides, metal-organics, and combinations. The gaseous precursors suitable for use with the present invention are not limited to those listed above. Suitable metal-organics include, but are not limited to, metal alkyls, metal alkoxides, metal dialkylamides, metal diketonates, or metal carbonyls, and combinations thereof.

The CVD is carried out in a reactor. Most reactors include gas and vapor delivery lines, a reactor main chamber having a hot wall and a cold wall. The reactor also includes substrate loading and unloading assembly for positioning the substrate within the reactor.

The reactor also includes an energy source(s). Typical examples of energy sources include resistive heating, radiant heating, and inductive heating. Resistive heating includes energy from a tube furnace or a quartz tungsten halogen lamp. Radiant heating provides energy from radio-frequency and inductive heating provided energy from a laser as a thermal energy source. Yet another energy source is photo energy from an UV-visible light laser.

The products from the CVD include a solid and a gas product. The solid gas products include thin films and powders. The thin films may be metals, alloys, ceramics and polymeric materials. The gas products are volatile byproducts and are always formed. The gas products generated in CVD processes are usually hazardous and must be disposed of accordingly.

Another type of CVD is plasma enhanced CVD (PECVD). PECVD is performed in a reactor at temperatures up to ˜1000° C. The deposited film is a product of a chemical reaction between the source gases supplied to the reactor. A plasma is generated in the reactor to increase the energy available for the chemical reaction at a given temperature. The system for carrying out the PECVD is similar to that described above for CVD.

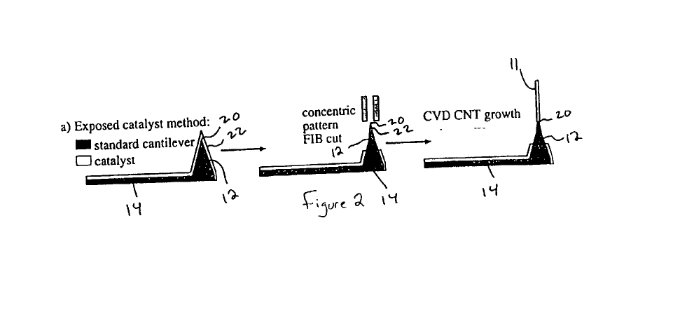

The subject invention, as shown in FIG. 2, includes a method of coating the regular cantilever 14 with the catalyst 22 material. Then a focused ion-beam (FIB) technique is used to remove the catalyst 22 below the apex 20 of the cantilever 14. As described elsewhere herein, the FIB technique is utilized for many purposes in the present invention. For example, the FIB technique is utilized to deposit, remove, and cut various components, such as the catalytic material 22 or the tip 12. The FIB technique is understood by those skilled in the art. In the embodiment of FIG. 2, the FIB does not remove the catalyst 22 from the very top of the apex 20. The FIB uses an ion beam to expose the surface of a sample by removing material from the sample with surgical precision. The FIB techniques may also be used to deposit material, such as the catalytic material 22, with the same precision as removing, and is described further below. Next, the catalyst 22 is subjected to either CVD or PECVD, and the CVD or the PECVD is used to grow a CNT 11 on the spared catalyst 22 patch resulting in a single CNT 11 standing on the apex 20.

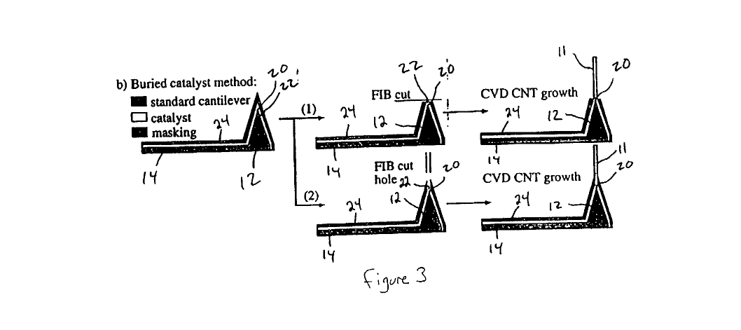

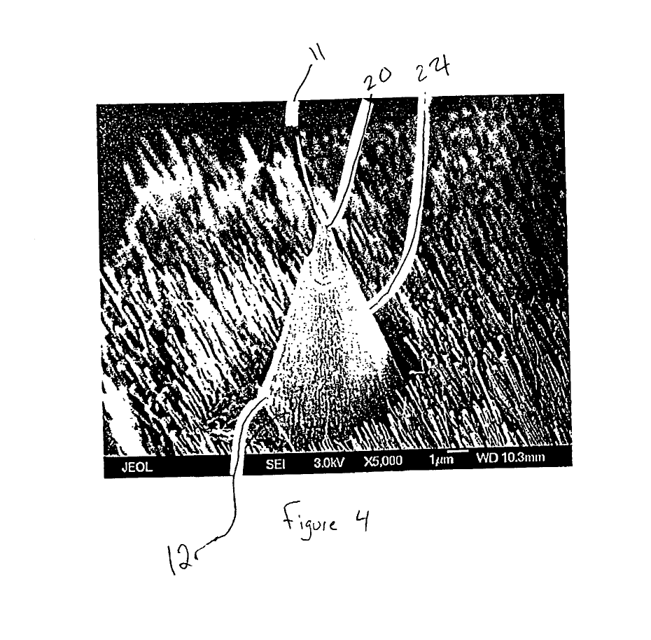

Another embodiment of the subject invention, illustrated in FIG. 3, coats the cantilever 14 with the catalyst 22 and a masking layer 24 consisting of a material not catalytically active for CNT 11 growth. More specifically, the masking layer 24 is selected from the group consisting of SiO, SiO₂, SiO₃, SiO₄, Cr, and combinations thereof. Then FIB is used to cut off the top of the apex 20, exposing a patch of the catalyst 22 material. Alternately, the FIB may cut a hole through the masking layer 24 at the apex 20 resulting in exposed catalyst 22 at the bottom of the hole. After the catalyst 22 has been exposed, CVD or PECVD is used to grow single CNTs 11 from the exposed catalyst 22 areas. FIG. 4 is a photograph of the cantilever 14 having the single CNT 11 grown according to this embodiment where the FIB has cut off the top of the apex 20. The single CNT 11 is about 6 μm long, 200 nm wide and at a 10 deg angle to the tip 12 normal. This angle was introduced deliberately to compensate for the cantilever 14 arm tilt when installed in the AFM 10.

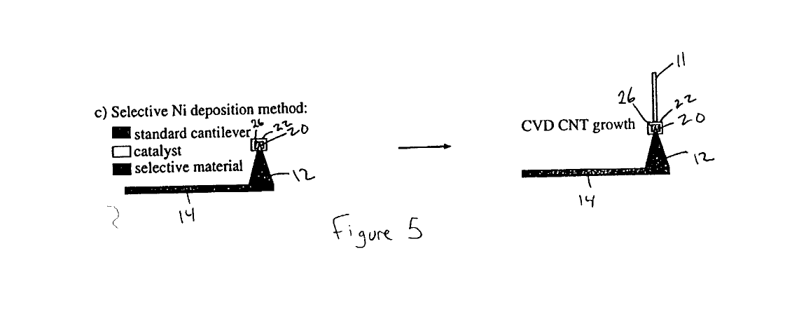

Yet another embodiment of the subject invention, illustrated in FIG. 5, uses an electroless plating technique to selectively deposit a patch of catalyst 22 at the end of the apex 20 of the tip 12 of the standard cantilever 14. The selectivity is accomplished by FIB assisted deposition of a material 26 on the apex 20. The material 26 sensitizes the electroless plating process, which is chemically tuned not to coat the bare cantilever 14 material. After the FIB deposition, catalyst 22 is electrolessly deposited on top of the sensitizing material 26 but not on the other parts of the cantilever 14. Then CVD or PECVD are used to grow the single CNT 11 on the catalyst 22 patch.

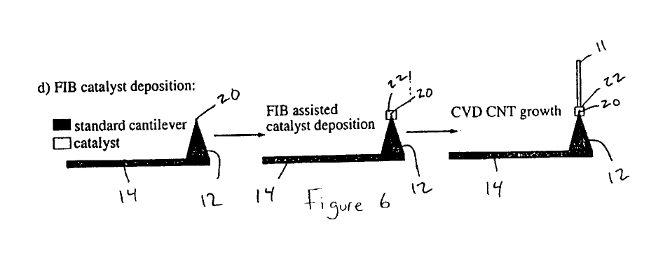

Referring to FIG. 6, still another embodiment of the subject invention is illustrated. A suitable precursor containing catalyst 22 material such as organometallic compounds is selected and applied to the cantilever 14. Next, the FIB is used to directly coat the apex 20 of the cantilever 14 with a patch of catalyst 22 material. The CNT 11 is then grown directly on that patch by CVD or PECVD.

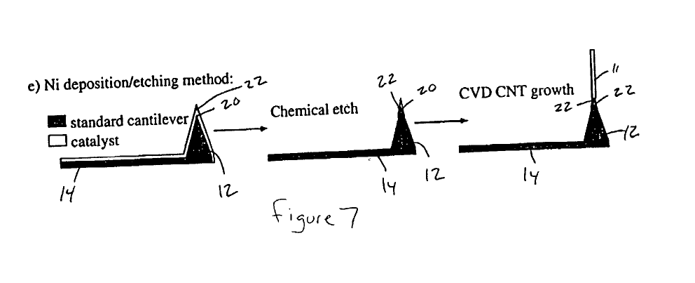

Lastly, the subject invention provides still a further embodiment by coating the regular cantilever 14 with catalyst 22 material using a deposition source positioned directly in a line-of-sight above the apex 20 of the tip 12, as shown in FIG. 7. The position of the deposition source directly in line with the apex results in a thinner coating on the slopes of the tip 12 than on the apex 20 and the cantilever 14 beam. Then, the catalyst 22 layer is etched chemically or electrochemically until the catalyst 22 is removed from the tip 12 slopes but some catalyst 22 remains on top of the apex 20 and the flat areas of the cantilever 14 beam. Then CVD or PECVD are used to grow a CNT 11 on the spared catalyst 22 patch resulting in a single standing CNT 11 standing on the apex 20.

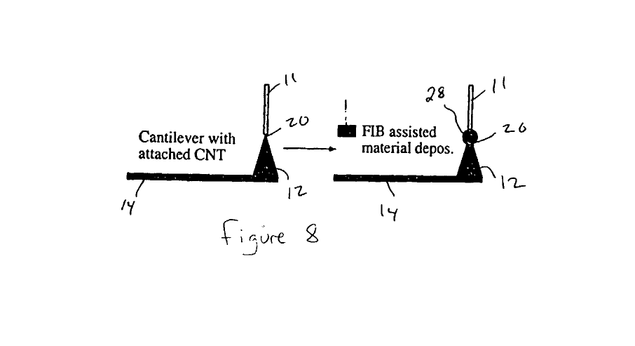

Referring to FIG. 8, any of the above embodiment may further a step of increasing the rigidity of the CNT 11 tips. Using the FIB, a suitable material 28, for example Pt, is deposited around the area where the CNT 11 is attached to the original cantilever 14. The suitable material 28 will enhance the mechanical attachment of the CNT 1 to the apex 20 of the cantilever 14 and enhance the lifetime of the CNT 11 during scanning operation.

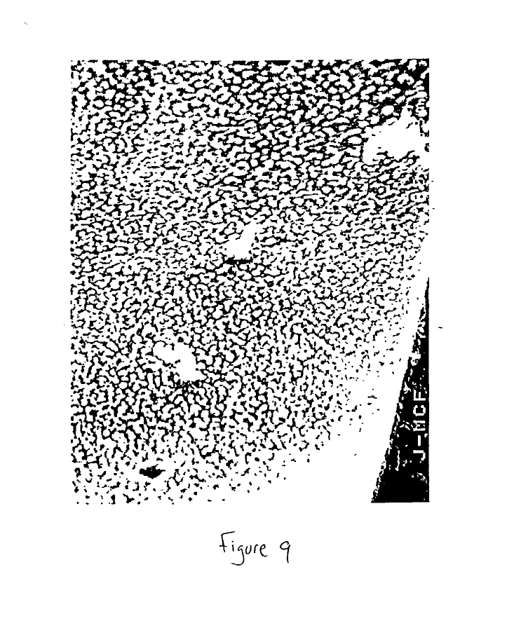

Referring to FIG. 9, a single CNT 11 was grown from sockets. The CNT 11 grown from sockets shown was enabled by previously depositing/growing a multiple layer structure of SiOx, Ni, SiOx and Pt. After deposition, the sockets were machined using the focused ion beam (FIB) technique.

It is to be understood that the subject method invention may also include the step of controlling an angle that the CNT 11 grows at relative to the apex 20 of the tip 12. This step may be necessary if it is desirable to provide an offset for any tilt of the cantilever 14. More specifically, an electric field is applied as the catalytic material 22 is subjected to CVD.

The diameter of the CNT 11 and the number of walls present in the CNT 11 may also be controlled. To control these features of the CNT 11, an amount of the catalytic material 22 that is deposited onto the apex 20 of the tip 12 is controlled. This varies the diameter of the CNT 11 and can also vary the number of walls of the CNT 11. A length of the CNT 11 can also be varied. To vary the length of the CNT 11, a duration of the CVD, or PECVD, is controlled.

Obviously, many modifications and variations of the present invention are possible in light of the above teachings. The invention may be practiced otherwise than as specifically described within the scope of the appended claims.

What is claimed is:

1. A method of producing a carbon nanotube for use with an atomic force microscope, wherein the atomic force includes a cantilever having a tip that culminates with an apex, said method comprising the steps of:
depositing a catalytic material onto the apex of the tip of the atomic force microscope; and
subjecting the catalytic material to chemical vapor deposition to initiate growth of the carbon nanotube such that the carbon nanotube extends from the apex of the tip.

2. A method as set forth in claim 1 wherein the step of depositing the catalytic material onto the apex of the tip is further defined as depositing a catalytic material selected from the group consisting of nickel, cobalt, iron, and combinations thereof.

3. A method as set forth in claim 1 wherein the step of subjecting the catalytic material to chemical vapor deposition comprises the step of transforming a gaseous precursor selected from the group consisting of hydrides, halides, metal-organics, and combinations thereof into a solid material.

4. A method as set forth in claim 1 wherein the step of subjecting the catalytic material to chemical vapor deposition is further defined as subjecting the catalytic material to plasma enhanced chemical vapor deposition.

5. A method as set forth in claim 1 further comprising the step of removing at least a portion of the catalytic material below the apex of the tip such that a patch of the catalytic material is spared at the apex after the catalytic material has been deposited, but prior to subjecting the catalytic material to chemical vapor deposition.

6. A method as set forth in claim 5 wherein the step of removing at least a portion of the catalytic material is further defined as removing at least a portion of the catalytic material using focused ion beam removal.

7. A method as set forth in claim 1 wherein the step of depositing the catalytic material onto the apex of the tip is further defined as depositing the catalytic material onto the apex of the tip using focused ion beam deposition.

8. A method as set forth in claim 7 further comprising the step of removing at least a portion of the catalytic material below the apex of the tip such that a patch of the catalytic material is spared at the apex after the catalytic material has been deposited, but prior to subjecting the catalytic material to chemical vapor deposition.

9. A method as set forth in claim 8 wherein the step of removing at least a portion of the catalytic material is further defined as removing at least a portion of the catalytic material using focused ion beam removal.

10. A method as set forth in claim 8 wherein the step of removing at least a portion of the catalytic material is further defined as removing at least a portion of the catalytic material using chemical etching.

11. A method as set forth in claim 8 wherein the step of removing at least a portion of the catalytic material is further defined as removing at least a portion of the catalytic material using electrochemical etching.

12. A method as set forth in claim 1 further comprising the step of coating the cantilever with a masking layer after the catalytic material has been deposited onto the apex of the tip.

13. A method as set forth in claim 12 wherein the step of coating the cantilever with the masking layer is further defined as coating the cantilever with a masking layer that is catalytically inactive for growth of the carbon nanotube.

14. A method as set forth in claim 13 wherein the step of coating the cantilever with the masking layer that is catalytically inactive for growth of the carbon nanotube is further defined as coating the cantilever with a masking layer selected from the group consisting of SiO, SiO₂, SiO₃, SiO₄, Cr, and combinations thereof.

15. A method as set forth in claim 12 further comprising the step of exposing at least a portion of the catalytic material after the cantilever has been coated with the masking layer, but prior to subjecting the catalytic material to chemical vapor deposition.

16. A method as set forth in claim 15 wherein the step of exposing at least a portion of the catalytic material is further defined as cutting off at least a portion of the tip of the cantilever to expose the portion of the catalytic material beneath the masking layer.

17. A method as set forth in claim 16 wherein the step of cutting off at least a portion of the tip of the cantilever is further defined as cutting off at least a portion of the tip of the cantilever using focused ion beam cutting.

18. A method as set forth in claim 15 wherein the step of exposing at least a portion of the catalytic material is further defined as cutting a hole through the masking layer at the apex to expose the portion of the catalytic material beneath the masking layer.

19. A method as set forth in claim 18 wherein the step of cutting a hole through the masking layer at the apex is further defined as cutting a hole through the masking layer at the apex using focused ion beam cutting.

20. A method as set forth in claim 15 wherein the step of subjecting the catalytic material to chemical vapor deposition is further defined as subjecting the exposed portion of the catalytic material to chemical vapor deposition.

21. A method as set forth in claim 1 further comprising the step of depositing a sensitizing material on the apex prior to deposition of the catalytic material onto the apex.

22. A method as set forth in claim 21 wherein the step of depositing the sensitizing material on the apex is further defined as depositing the sensitizing material on the apex using focused ion beam deposition.

23. A method as set forth in claim 21 wherein the step of depositing the catalytic material onto the apex of the tip is further defined as depositing the catalytic material on top of the sensitizing material using electroless plating.

24. A method as set forth in claim 1 further comprising the step of controlling an angle that the carbon nanotube grows at relative to the apex of the tip.

25. A method as set forth in claim 24 wherein the step of controlling the angle that the carbon nanotube grows at is further defined as applying an electric field as the catalytic material is subjected to chemical vapor deposition.

26. A method as set forth in claim 1 wherein the step of depositing the catalytic material onto the apex of the tip comprises the step of controlling an amount of the catalytic material that is deposited onto the apex of the tip to vary at least one of a diameter of the carbon nanotube and a number of walls present in the carbon nanotube.

27. A method as set forth in claim 1 wherein the step of subjecting the catalytic material to chemical vapor deposition comprises the step of controlling a duration of the chemical vapor deposition to vary a length of the carbon nanotube.

28. A method as set forth in claim 1 further comprising the step of increasing the rigidity of the carbon nanotube that extends from the apex of the tip.

29. A method as set forth in claim 28 wherein the step of increasing the rigidity of the carbon nanotube is further defined as depositing platinum onto the apex of the tip prior to deposition of the catalytic material onto the apex.

30. A method as set forth in claim 29 wherein the step of depositing platinum onto the apex of the tip is further defined as depositing platinum onto the apex of the tip using focused ion beam deposition.
